(19) United States
(12) Patent Application Publication
(10) Pub. No.: US 2010/0108369 A1
(43) Pub. Date: May 6, 2010

(54) Printed Circuit Boards, Printed Circuit Board Capacitors, Electronic Filters, Capacitor Forming Methods, and Articles of Manufacture

(76) Inventor: Alexander Tom, Cupertino, CA (US)

Correspondence Address: WELLS ST. JOHN P.S., 601 W. FIRST AVENUE, SUITE 1300, SPOKANE, WA, 99201, US

(21) Appl. No.: 12/262,979

(22) Filed: Oct. 31, 2008

(51) Int. Cl. H05K 1/11; H05K 1/16; H01R 43/00; G06F 17/50

(52) U.S. Cl. 174/260; 174/266; 29/877; 716/4

(57) ABSTRACT

Printed circuit board capacitors include a first electrode comprising a via extending at least partially through a multi-layer printed circuit board and a plurality of conductive pads in electrical contact with the via and extending radially outward from the via, and a second electrode electrically isolated from the first electrode and comprising a plurality of ground-plane layers of the printed circuit board. The plurality of ground-plane layers include electrically conductive material overlapping the plurality of conductive pads.

### TECHNICAL FIELD

The present invention, in various embodiments, relates to printed circuit boards, printed circuit board capacitors, electronic filters, capacitor forming methods, and articles of manufacture.

### BACKGROUND OF THE INVENTION

Many electronic devices, such a packet switches, need to meet stringent electromagnetic emissions standards such as Federal Communication Commission (FCC) standards and Network Equipment Building System (NEBS) standards. Devices that have high-frequency clock speeds (e.g., multiple gigahertz speeds) or high-frequency data rates (e.g., multiple gigabit speeds) have the potential to emit high-frequency noise that if not suppressed may jeopardize compliance with emissions standards. The high-frequency noise may be generated by, for example, phase-locked loops in serializer/deserializers (SerDes) and may be radiated by a printed circuit board and/or packaging of an electronic device.

In some cases, filters constructed from lumped elements (e.g., capacitors and inductors) might not be effective at filtering high-frequency noise, for example, because they might not have a high enough cutoff frequency and/or may exhibit undesirable secondary effects. Furthermore, these filters may consume an unacceptably large amount of printed circuit board space.

Stepped-impedance transmission-line filters may also be considered for filtering the high-frequency noise. These filters may be formed using segments of transmission line (e.g., microstrip segments or stripline segments) having various widths and lengths. The widths and lengths may vary based on a desired cutoff frequency and a desired amount of attenuation to be provided by the filter. The widths and lengths may be determined using known filter design techniques.

However, to sufficiently attenuate the high-frequency noise, the lengths of segments of a stepped-impedance transmission-line filter may be so long that implementing the filter on a densely populated printed circuit board may be impractical.

### BRIEF DESCRIPTION OF THE DRAWINGS

Preferred embodiments of the invention are described below with reference to the following accompanying drawings.

FIG. 1 is a cross-sectional diagram of a printed circuit board according to one embodiment.

FIG. 2 is an isometric view of volumes of a printed circuit board according to one embodiment.

FIG. 3 is a top view of areas of a printed circuit board according to one embodiment.

FIG. 4 is another top view of areas of a printed circuit board according to one embodiment.

FIG. 5 is an isometric view of portions of a printed circuit board according to one embodiment.

FIG. 6 is an exploded view of layers of a printed circuit board according to one embodiment.

FIG. 7 is another exploded view of layers of a printed circuit board according to one embodiment.

FIG. 8 is a chart illustrating attenuation of a filter according to one embodiment.

FIG. 9 is a diagram of a stepped-impedance transmission-line filter according to one embodiment.

FIG. 10 is a schematic diagram of a filter according to one embodiment.

FIG. 11 is a schematic diagram of another filter according to one embodiment.

FIG. 12 is a top view of a filter according to one embodiment.

FIG. 13 is a top view of another filter according to one embodiment.

FIG. 14 is a top view of another filter according to one embodiment.

FIG. 15 is an isometric view of a filter according to one embodiment.

FIG. 16 is a isometric view of another filter according to one embodiment.

### DETAILED DESCRIPTION OF THE PREFERRED EMBODIMENTS

According to one aspect of the invention, a multi-layer printed circuit board includes a first volume, a second volume contained by the first volume, a third volume comprising a section of the first volume that is not within the second volume, and a plurality of plies. The plurality of plies includes a ply comprising a conductive pad on a first substrate. The conductive pad extends within the first volume, the second volume, and the third volume, but not outside of the first volume. The conductive pad may be circular and may fill a first cross section of the third volume.

The plurality of plies also includes at least one ground ply comprising a patterned layer of conductive material on a second substrate. A portion of the patterned layer extends within the third volume but does not extend within the second volume. The portion of the patterned layer is elevationally directly above the conductive pad and may fill a second cross section of the third volume.

The printed circuit board also includes a via electrically connected to the conductive pad. The via extends through the plurality of plies and through the second volume. The third volume may surround the via and the via might not extend into the third volume.

The first substrate may electrically insulate the portion of the patterned layer from the conductive pad and the second substrate may electrically insulate the via from the portion of the patterned layer. The first substrate may be in physical contact with both the conductive pad and the patterned layer of conductive material.

In some configurations, the portion of the patterned layer may be referred to as a first portion and the multi-layer printed circuit board may further include a fourth volume and at least one additional ply comprising a second patterned layer of conductive material on a third substrate. A second portion of the second patterned layer of conductive material may extend outside of the fourth volume but might not extend within the first volume or the second volume. The first volume may be within the fourth volume and the first portion may extend outside of the fourth volume.

According to another aspect of the invention, a printed circuit board capacitor includes a first electrode and a second electrode. The first electrode includes a via extending at least partially through a multi-layer printed circuit board and a plurality of conductive pads in electrical contact with the via and extending radially outward from the via. Individual conductive pads of the plurality of conductive pads may be comprised by different layers of the multi-layer printed circuit board relative to one another and may surround different cross sections of the via relative to one another. In some embodiments, the plurality of conductive pads may include at least six pads.

The via may include a cylindrically shaped electrically conductive material positioned within an opening formed in the printed circuit board.

The second electrode is electrically isolated from the first electrode and includes a plurality of ground-plane layers of the printed circuit board. The plurality of ground-plane layers includes electrically conductive material overlapping the plurality of conductive pads. In some embodiments, at least fifty percent of the surface area of at least one of the conductive pads of the plurality may be elevationally directly below the electrically conductive material. The ground-plane layers of the plurality may be electrically connected to each other and may be interposed with the plurality of conductive pads.

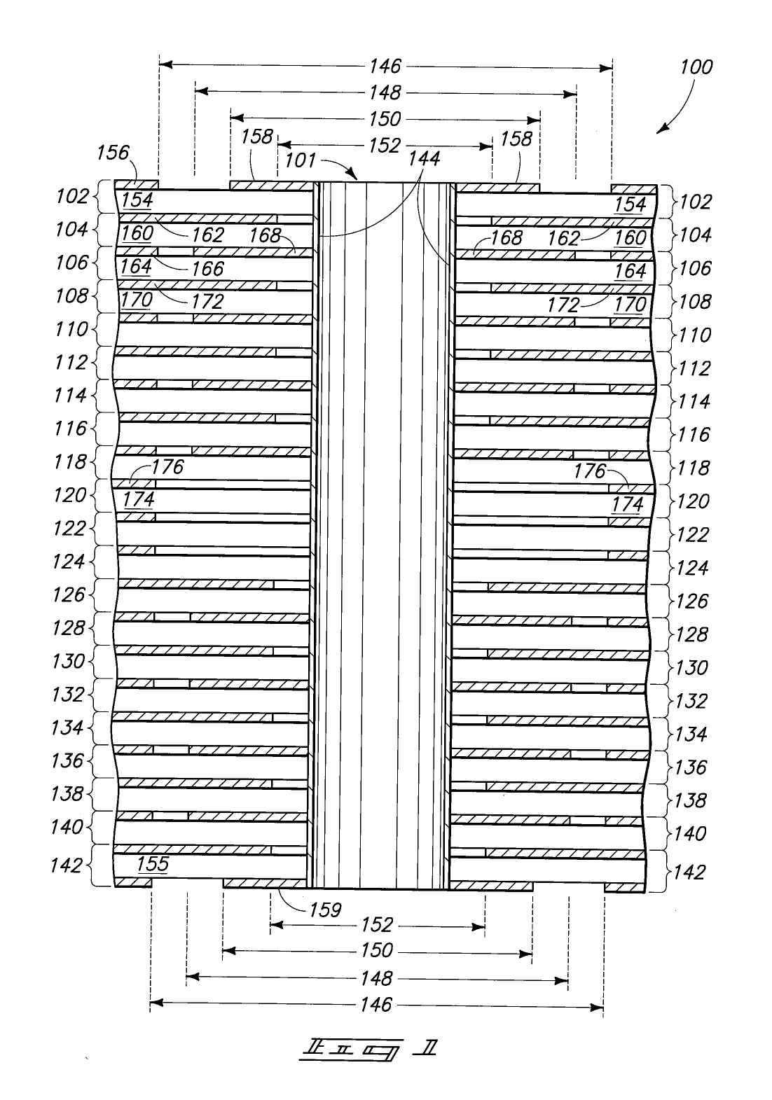

Referring to FIG. 1, a cross-sectional diagram of a portion of a printed circuit board 100, according to one embodiment, is illustrated. Printed circuit board 100 is a multi-layer printed circuit board made up of a plurality of plies 102, 104, 106, 108, 110, 112, 114, 116, 118, 120, 122, 124, 126, 128, 130, 132, 134, 136, 138, 140, and 142.

In one embodiment, the plies of printed circuit board 100 are individually fabricated and then bonded together. Fabricating an individual ply may include providing an electrically insulative substrate, forming a layer of electrically conductive material on a surface of the substrate, and etching the layer to remove portions of the conductive material so that a desired pattern of conductive material remains on the substrate. The resulting patterned layer of conductive material may include one or more “pads.” As used herein, the terms pad and conductive pad refer to a contiguous portion of conductive material formed on a substrate (e.g., by etching). Although the pads depicted in the Figures are circular, the term pad as used herein is intended to encompass pads of non-circular shape (e.g., polygonal shapes such as squares).

In one embodiment, each of plies 102, 104, 106, 108, 110, 112, 114, 116, 118, 120, 122, 124, 126, 128, 130, 132, 134, 136, 138, 140, and 142 comprises a different substrate and a different patterned layer of conductive material relative to one another.

Some plies of printed circuit board 100 may be configured to perform a particular function. For example, plies 102, 106, 110, 114, 118, 128, 132, 136, and 140 may be signal plies including patterned layers of conductive material that electrically connect pins of electrical components (e.g., integrated circuits) mounted on printed circuit board 100.

Plies 104, 108, 112, 116, 126, 130, 134, and 138 may be ground plane plies including patterned layers of conductive material configured to be tied to a particular low electrical potential or voltage. In some embodiments, the patterned layers of conductive material of the ground-plane plies may be electrically connected to each other.

Plies 120, 122, and 124 may be power plies including patterned layers of conductive material configured to be tied to a particular voltage having a higher potential than the low voltage to which the patterned layers of conductive material of the ground-plane plies are tied. The voltage tied to the patterned layers of conductive material of the power plies may be a supply voltage supplied to electrical components mounted on printed circuit board 100. In some configurations, the patterned layers of conductive material of the individual power plies may be tied to different supply voltages relative to one another.

Ply 142 may be a double-sided ply having a patterned layer of conductive material used to connect electrical components together on one side of a substrate and a patterned layer of conductive material tied to the low voltage on the other side of the substrate.

Printed circuit board 100 also includes a via 144 that extends through plies 102, 104, 106, 108, 110, 112, 114, 116, 118, 120, 122, 124, 126, 128, 130, 132, 134, 136, 138, 140, and 142. Via 144 may be formed in an opening extending through the plies. In one embodiment, the opening may be formed by drilling a hole through the plies. Via 144 may be formed by lining the opening with a conductive material (e.g., by electroplating the opening with a metallic material). If the opening is cylindrical, the conductive material may be cylindrically shaped.

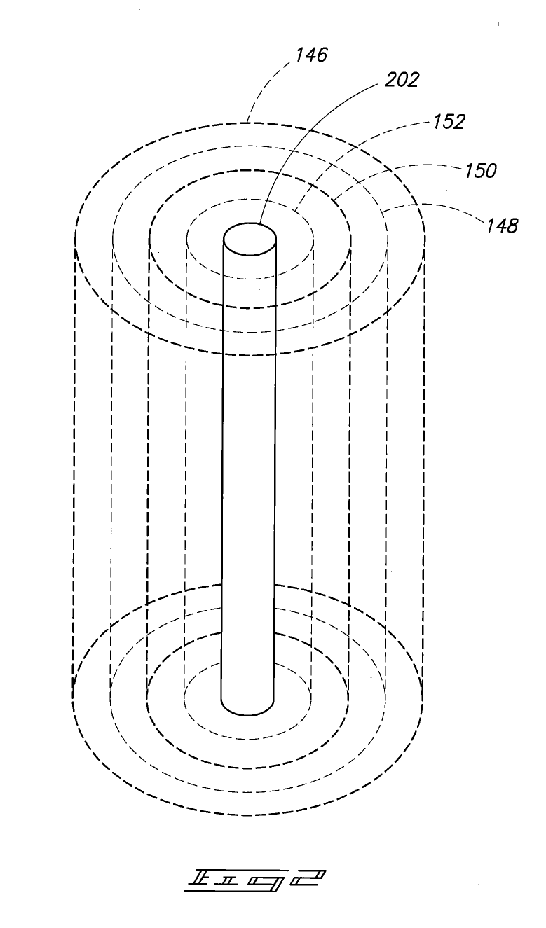

In FIG. 1, a cross-sectional side view of via 144 is depicted that illustrates a conductive material lining the opening as a shaded rectangle. An opening associated with via 144 that extends through printed circuit board 100 is not visible in FIG. 1, but is illustrated in FIGS. 2-5, which are described below.

In some configurations, the opening may be drilled after plies 102, 104, 106, 108, 110, 112, 114, 116, 118, 120, 122, 124, 126, 128, 130, 132, 134, 136, 138, 140, and 142 have been bonded together. In other configurations, individual holes may be drilled in layers 102, 104, 106, 108, 110, 112, 114, 116, 118, 120, 122, 124, 126, 128, 130, 132, 134, 136, 138, 140, and 142 prior to the plies being bonded. In these configurations, the individually drilled holes may be aligned during the process of bonding the plies together.

Via 144 may be electrically and/or physically in contact with some of the patterned layers of conductive material of the plies of printed circuit board 100 and in some cases may electrically connect two or more of the layers together. For example, ply 102 includes a conductive pad 158 formed on a substrate 154. As illustrated in FIG. 1, pad 158 is in physical contact with via 144 and is therefore electrically connected to via 144. Furthermore, pad 168 of ply 106 is also in physical contact with via 144 and is therefore electrically connected to both via 144 and pad 158.

Various volumes 146, 148, 150, and 152 have been defined herein to aid in describing the relative positions of the patterned layers of conductive material of the plies of printed circuit board 100. Volumes 146, 148, 150, and 152 are three-dimensional shapes that encompass various portions of printed circuit board 100. In FIG. 1, side views of volumes 146, 148, 150, and 152 are illustrated, so the volumes appear two dimensional.

Referring to FIG. 2, an isometric view of volumes 146, 148, 150, and 152 is illustrated. In addition, FIG. 2 illustrates opening 202 that extends through the plies of printed circuit board 100 and in which via 144 is formed. Note that opening 202 is centered within volumes 146, 148, 150, and 152. FIG. 2 illustrates positions of the volumes relative to one another, but does not illustrate other portions of printed circuit board 100, other than opening 202, for simplicity.

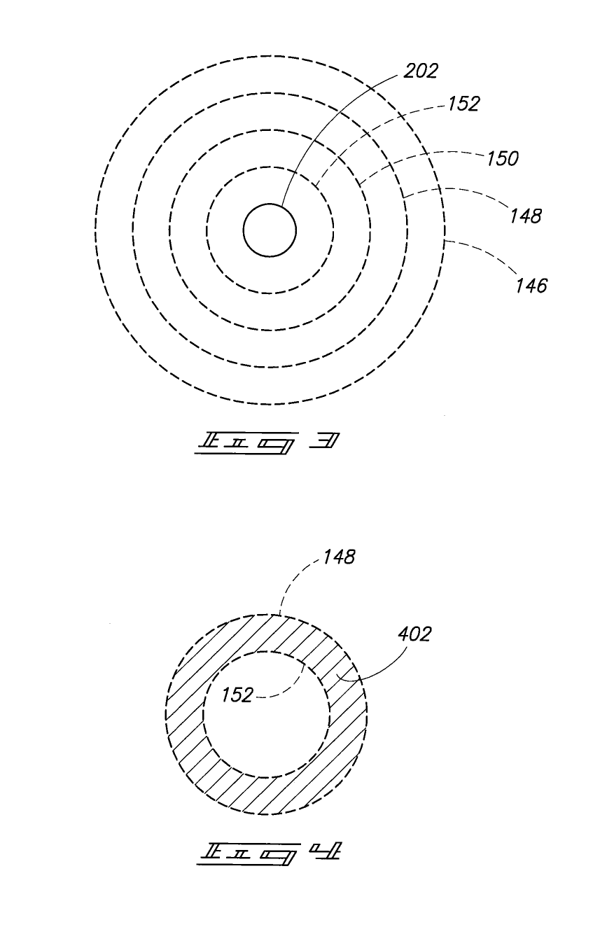

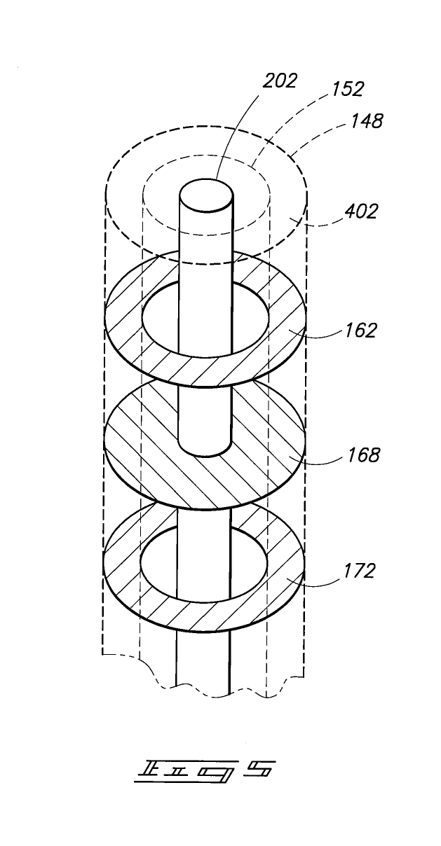

Referring to FIG. 3, a top (plan) view of volumes 146, 148, 150, and 152 and opening 202 is illustrated. These volumes are further illustrated in FIGS. 4-5.

Referring to FIG. 4, a top (plan) view of volumes 148 and 152 is illustrated. In addition, a volume 402 is illustrated. Volume 402 consists of the portions of volume 148 that are not within volume 152. These portions of volume 148 are shaded in FIG. 4.

Volumes 146, 148, 150, and 152 contain different portions of printed circuit board 100 relative to one another. Note that volume 146 contains volumes 148, 150, and 152. Similarly, volume 148 contains volumes 150 and 152 and volume 150 contains volume 152.

Returning now to FIG. 1, ply 102 includes substrate 154 and a patterned layer of conductive material. The patterned layer of conductive material includes a pad 158 and a signal trace 156. As was mentioned above, substrate 154 may be electrically insulative and the patterned layer of conductive material, including pad 158 may be electrically conductive. Furthermore, pad 158 may be circular when viewed from above (plan view).

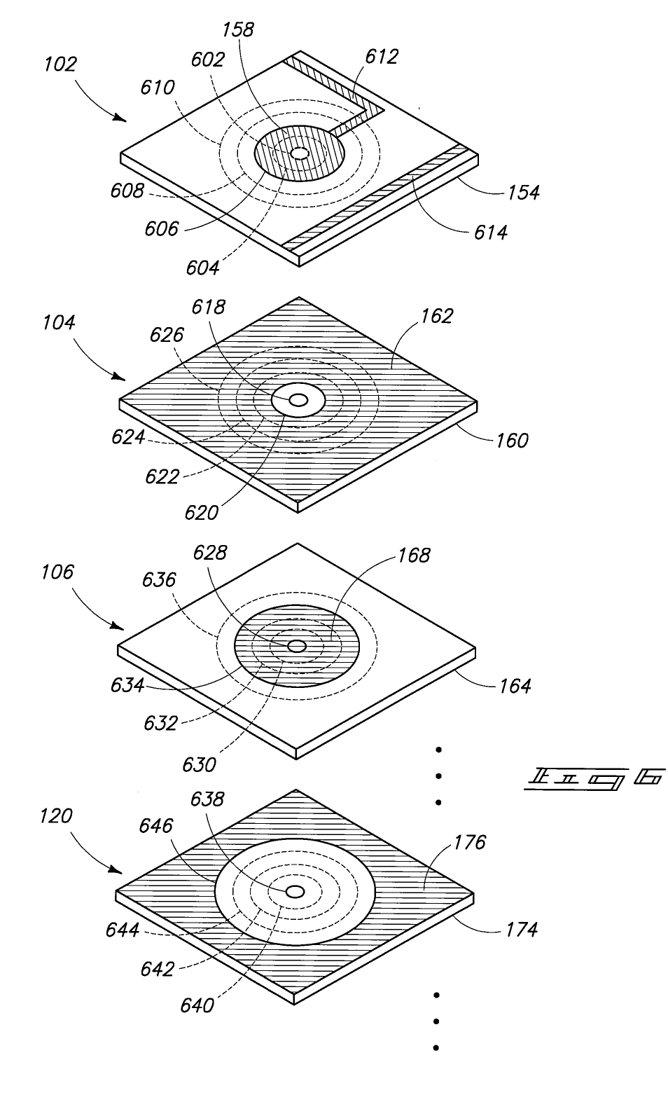

As illustrated in FIG. 1, pad 158 extends within volume 152 and volume 150, but does not extend outside of volume 150. In one embodiment, pad 158 may be compliant with a design rule specifying that pads on a top surface of printed circuit board 100 should fill at least a horizontal cross section of volume 150. Of course, a portion of the pads may be later removed when creating opening 202, in which case the pads fill at least the horizontal cross section of volume 150 except for opening 202. Pad 158 may be in physical contact with and electrically connected to via 144. In addition, pad 158 may be electrically connected to another portion of the patterned layer of conductive material of ply 102, such as circuit trace 612 illustrated in FIG. 6 and described below.

Ply 142 includes substrate 155 and a patterned layer of conductive material. The patterned layer of conductive material may include pad 159, which may have substantially the same dimensions as pad 158 and may be electrically connected via another portion of the patterned layer of electrically conductive material of ply 142 to an electronic component mounted on printed circuit board 100.

Ply 104 includes substrate 160 and a patterned layer of conductive material 162. The patterned layer of conductive material extends outside of volume 146 and within volumes 146, 148, and 150 but does not extend within volume 152. As was described above, patterned layer 162 may form a ground plane and may be electrically connected to a ground voltage.

A design rule may specify that patterned layer 162 may not extend within volume 152. This rule, along with the dimensions of volume 152 may ensure that adequate space exists between patterned layer 162 and via 144 so that patterned layer 162 does not make electrical contact with via 144.

Ply 106 includes substrate 164 and a patterned layer of conductive material. The patterned layer of conductive material includes a pad 168 and a signal trace 166. As with pad 158 and other pads described herein, pad 168 may be circular when viewed from above (plan view).

Pad 168 extends within volume 152, volume 150, and volume 148 but does not extend outside of volume 148. In contrast to pads 158 and 159, which may be connected to circuit traces leading to electrical components of printed circuit board 100, pad 168 might not physically be in contact with an electrically conductive material other than via 144, such as circuit trace 166.

A design rule may specify that portions of the patterned layer of conductive material of ply 106 other than pad 168 (e.g., circuit trace 166) may not extend within volume 146. This rule, along with the dimensions of volume 146 and 148 may ensure that adequate space exists between pad 168 and the balance of the patterned layer of conductive material of ply 106 (all of the patterned layer of ply 106 other than pad 168) so that the balance of the patterned layer of conductive material of ply 106 does not make electrical contact with pad 168. Thus, as is illustrated in FIG. 1, the balance of the patterned layer of conductive material of ply 106 is not in physical or electrical contact with pad 168.

As illustrated in FIG. 1, pad 168 may be larger than pad 158. Specifically, pad 168 may extend outside of volume 150 whereas pad 158 may be confined within volume 150. As was noted above, pad 158 may be connected to a circuit trace formed on substrate 154. In contrast, pad 168 might not be physically connected to any other electrically conductive node other than via 144. This is different from known pads located on internal plies of printed circuit boards because the purpose of known pads located on internal plies is to connect a via to another electrically conductive node, such as a circuit trace connected to an electrical component mounted on the board.

Ply 108 includes substrate 170 and a patterned layer of conductive material 172. As with patterned layer 162, patterned layer 172 extends outside of volume 146 and within volumes 146, 148, and 150 but does not extend within volume 152. Like patterned layer 162, patterned layer 172 may form a ground plane and may be electrically connected to both the ground voltage and patterned layer 162.

Substrate 160 may insulate patterned layer 162 from pad 168. Pad 168 may be in direct physical contact with substrate 160 and substrate 164. These two substrates may electrically insulate pad 168 from patterned layers 162 and 172 respectively. In addition, substrates 160 and 164 may electrically insulate via 144 from patterned layers 162 and 172 respectively.

Ply 120 includes substrate 174 and a patterned layer of conductive material 176. Patterned layer 176 extends outside of volume 146, but does not extend within volume 146. As was described above, patterned layer 176 may be a power layer configured to supply power to components installed on printed circuit board 100 and may be electrically connected to a supply voltage.

A design rule may specify that patterned layer 176 may not extend within volume 146. This rule, along with the dimensions of volume 146 may ensure that adequate space exists between patterned layer 176 and via 144 so that patterned layer 176 does not make electrical contact with via 144, may ensure that patterned layer 176 does not overlap with pad 168, and may ensure that patterned layer 176 is not elevationally directly below pad 168.

Referring to FIG. 5, an isometric view of some portions of printed circuit board 100 contained by volume 148 is illustrated including pad 168 and the portions of patterned layers 162 and 172 that are within volume 402. Note that for simplicity, substrates 160, 164, and 170 are not illustrated. Pad 168, patterned layer 162, and patterned layer 172 all extend within volume 402 and pad 168 is interposed between patterned layers 162 and 172. Accordingly, patterned layers 162 and 172 overlap pad 168 since patterned layer 162 is elevationally directly above pad 168 in volume 402 and patterned layer 172 is elevationally directly below pad 168 in volume 402. In one embodiment, at least fifty percent of the surface area of pad 168 is elevationally directly above patterned layer 172 and elevationally directly below patterned layer 162.

Pad 168 does not fully overlap either patterned layer 162 or patterned layer 172 since pad 168 extends within volume 152, but neither patterned layer 162 nor patterned layer 172 extends within volume 152. Furthermore, patterned layers 162 and 172 extend outside of volume 148 but pad 168 does not extend outside of volume 148. Thus, outside of volume 402, pad 168 is neither elevationally directly above nor elevationally directly below either patterned layer 162 or patterned layer 172.

Returning now to FIG. 1, pads having substantially the same dimensions as pad 168 are present in plies 110, 114, 118, 128, 132, 136, and 140. Like pad 168, these pads are also in physical and electrical contact with via 144.

Patterned layers that extend within volume 402 but not within volume 152, like patterned layers 162 and 172, are present in plies 112, 116, 126, 130, 134, 138, and 142. These patterned layers are interposed with the pads of plies 110, 114, 118, 128, 132, 136, and 140. Like patterned layers 162 and 172, these patterned layers are electrically isolated from the pads and from via 144 and may be electrically connected to each other and to a ground voltage. Accordingly, these patterned layers may be referred to as ground layers.

Via 144, the pads, and the ground layers form a via-pad-stack capacitor 101 in which via 144, pads 158, 159, 168, and the pads present in plies 110, 114, 118, 128, 132, 136, and 140 are a first electrode of the capacitor, the ground layers together are a second electrode of the capacitor, and the substrates of plies 104, 106, 108, 110, 112, 114, 116, 126, 128, 130, 132, 134, 136, 138, and 140 are the dielectric of the capacitor. The capacitance of the capacitor may be determined, at least in part, on the dimensions of volume 402 since the pads and the ground layers overlap within volume 402. The capacitance may also be determined, at least in part, on the number of pads.

Via 144 is significantly different from known vias, which are designed to minimize capacitance between signal layers and ground layers. In contrast, via 144 is electrically connected to the pads, which extend radially from via 144 and purposely overlap the ground layers to create capacitance.

Referring to FIG. 6, an isometric, exploded view of portions of some of the plies of printed circuit board 100 is illustrated. Note that the portions of printed circuit board 100 illustrated in FIGS. 1-7 may be very small portions of printed circuit board 100. Printed circuit board 100 may include tens, hundreds, or more vias similar to via 144. Furthermore, electronic components may be mounted on the top or bottom surface of printed circuit board 100. These components and additional vias, as well as some of the circuit traces and patterned layers of conductive material of FIG. 1, are not illustrated for simplicity. Instead, a small portion of printed circuit board 100 surrounding via 144 is illustrated.

FIG. 6 illustrates substrate 154 and pad 158 of ply 102. Circuit traces 612 and 614 are also illustrated. These traces, along with pad 158, may be part of the patterned layer of conductive material formed on substrate 154 described above. Note that trace 612 is physically and electrically connected to pad 158.

Cross sections of the volumes of FIG. 2 are illustrated on the plies of FIG. 6. Cross sections 604, 620, 630, and 640 are cross sections of volume 152; cross sections 606, 622, 632, and 642 are cross sections of volume 150; cross sections 608, 624, 634, and 644 are cross sections of volume 148; and cross sections 610, 626, 636, and 646 are cross sections of volume 146. In addition, cross sections 602, 618, 628, and 638 of opening 202 of via 144 are illustrated.

With respect to ply 102, pad 158 fills cross sections 606 and 604, but does not extend beyond cross section 606, although it is physically and electrically connected to trace 612.

With respect to ply 104, patterned layer 162 extends within cross sections 626, 624, and 622, but does not extend within cross section 620. Since patterned layer 162 fills the portions of cross section 624 that are not within cross section 620, it can be said that patterned layer 162 fills a cross section of volume 402 since cross section 624 is a cross section of volume 148, cross section 620 is a cross section of volume 152, and volume 402 is the portions of volume 148 that are not within volume 152.

With respect to ply 106, pad 168 fills cross sections 630, 632, and 634, but does not extend beyond cross section 634. The pads of via-pad-stack capacitor 101 not illustrated in FIG. 6 (i.e., the pads of plies 110, 114, 118, 128, 132, 136, and 140) also fill cross sections of volume 148. These pads fill different cross sections of volume 148 relative to one another since the pads are in different plies relative to one another and therefore at a different elevations relative to one another.

With respect to ply 120, patterned layer 176 extends outside of cross section 646, but not within cross section 646.

As was noted above, although pads 158 and 168 are depicted as being circular in FIG. 6, in some embodiments, pads 158 and 168 may have non-circular shapes that surround via 144.

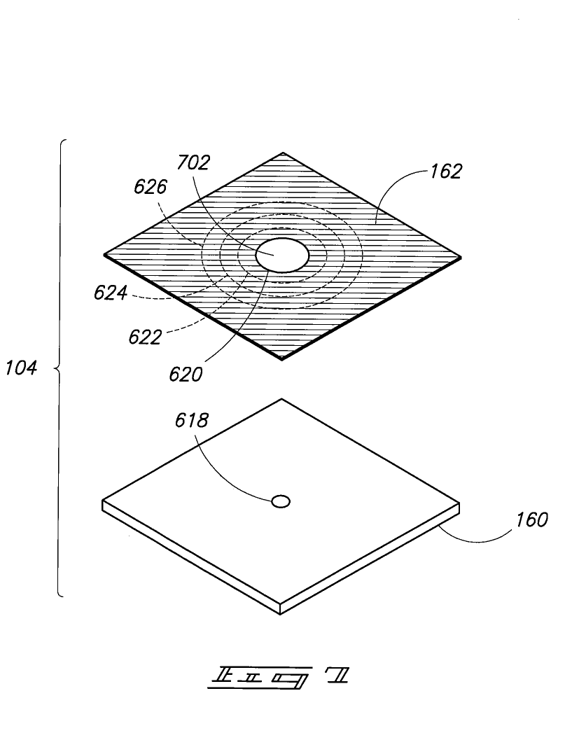

Referring to FIG. 7, an exploded view of ply 104 is illustrated. Ply 104 includes substrate 160 and patterned layer 162 formed on substrate 160. Patterned layer 162 may be formed by forming a layer of conductive material over substrate 160 and then etching portions of the layer away to form patterned layer of conductive material 162. In particular, patterned layer 162 may include opening 702, which may be formed via etching. Opening 702 may be substantially centered around cross section 618 of opening 202.

According to another aspect of the invention, a capacitor forming method includes forming a first printed circuit board ply including a conductive pad on a first substrate. The conductive pad has a first area. The method also includes forming a second printed circuit board ply comprising a layer of conductive material on a second substrate. The layer of conductive material includes a first opening surrounded by a portion of the conductive material. The first opening has a second area smaller than the first area.

The method also includes bonding the first printed circuit board ply to the second printed circuit board ply so that the conductive pad is elevationally directly above the first opening and is elevationally directly above the portion of the conductive material. The bonding may include bonding so that the conductive pad covers an entirety of the first opening.

The method also includes forming a second opening extending through the conductive pad, the first substrate, the first opening, and the second substrate.

In some embodiments, the conductive material may be referred to as a first conductive material and the method may further include forming a second conductive material within the second opening and in physical contact with the conductive pad but not in physical or electrical contact with the first conductive material.

Via-pad-stack capacitor 101 described above in relation to FIGS. 1-6 may be formed as follows. First, the individual plies (102, 104, 106, 108, 110, 112, 114, 116, 118, 120, 122, 124, 126, 128, 130, 132, 134, 136, 138, 140, and 142) of printed circuit board 100 may be formed by forming layers of conductive material on the substrates of the plies and then etching the layers of conductive material to form the patterned layers of conductive material and pads described above. The individual plies are then aligned and bonded together.

Opening 202 is formed through the plies. In some embodiments, opening 202 is formed in each individual ply of printed circuit board 100 prior to the plies being bonded together. In other embodiments, opening 202 is formed after the plies have been bonded together. Opening 202 is then lined or filled with a conductive material (e.g., a metallic material) that makes electrical contact with the pads but is not in electrical contact with the ground layers or power layers.

According to another aspect of the invention, an electronic filter includes a filter stage and an input node. The filter stage may be a lowpass filter stage configured to substantially attenuate signals presented at the input node having a frequency higher than a cutoff frequency of the filter stage and minimally attenuate signals presented at the input node having a frequency lower than the cutoff frequency.

The filter stage includes a first segment of transmission line formed on a printed circuit board. The first segment of transmission line may include a first segment of stripline or microstrip. The first segment has a first complex impedance and is configured to provide at least part of an inductive reactance of the filter stage. The filter stage also includes one or more vias extending through the printed circuit board. The one or more vias may be serially connected. A first end of a first one of the one or more vias is electrically connected to a first end of the first segment of transmission line. The one or more vias are configured to provide at least part of a capacitive reactance of the filter stage.

The input node includes a second segment of transmission line formed on the printed circuit board. The second segment of transmission line may include a second segment of stripline or microstrip. The second segment has a second complex impedance that is larger than the first complex impedance and the second segment is connected to either a second end of the first segment of transmission line, to the first end of the first one of the one or more vias, or to an end of a second one of the one or more vias.

The filter may further include an output node comprising a fourth segment of transmission line formed on the printed circuit board. The fourth segment may have the second complex impedance and may be physically connected to the third segment of transmission line.

The first segment and the second segment may be on a same side of the printed circuit board relative to one another. Alternatively, the first segment and the second segment may be on different sides of the printed circuit board relative to one another. The first segment and the second segment may have different widths relative to one another.

The printed circuit board may be a multi-layer printed circuit board and the filter stage may further include a plurality of conductive pads in electrical contact with the one or more vias and extending radially outward from the one or more vias. The printed circuit board may also include a plurality of ground-plane plies comprising patterned layers of electrically conductive material. Each ground-plane ply of the plurality may be elevationally directly above at least one conductive pad of the plurality of conductive pads. The plurality of ground-plane plies may be electrically connected to each other and electrically isolated from the plurality of conductive pads.

The one or more vias and the plurality of conductive pads may form a first electrode of a capacitor and the electrically connected plurality of ground-plane layers may form a second electrode of the capacitor.

In one embodiment, the one or more vias may include two or more vias serially connected together with one end of the serially connected two or more vias being connected to the first segment of transmission line and the other end of the serially connected two or more vias not being electrically connected to any other conductive node of the printed circuit board.

The filter stage may be referred to as a first filter stage and the one or more vias may be referred to as a first set of one or more vias. The electronic filter may further include a second filter stage having a third segment of transmission line formed on the printed circuit board and having the first complex impedance and a length different than a length of the first segment of transmission line. The electronic filter may also include a second set of two or more serially connected vias extending through the printed circuit board, the second set comprising a different quantity of vias than the first set.

Referring to FIG. 8, a chart 800 depicting a frequency response of a low-pass filter is illustrated. As illustrated by the frequency response, the low-pass filter is configured to minimally attenuate frequencies lower than a cutoff frequency f_{c} and to substantially attenuate frequencies higher than f_{c}.

One way to implement a low-pass filter on a printed circuit board is to form a stepped-impedance transmission-line filter in a patterned layer of conductive material on a substrate of the printed circuit board.

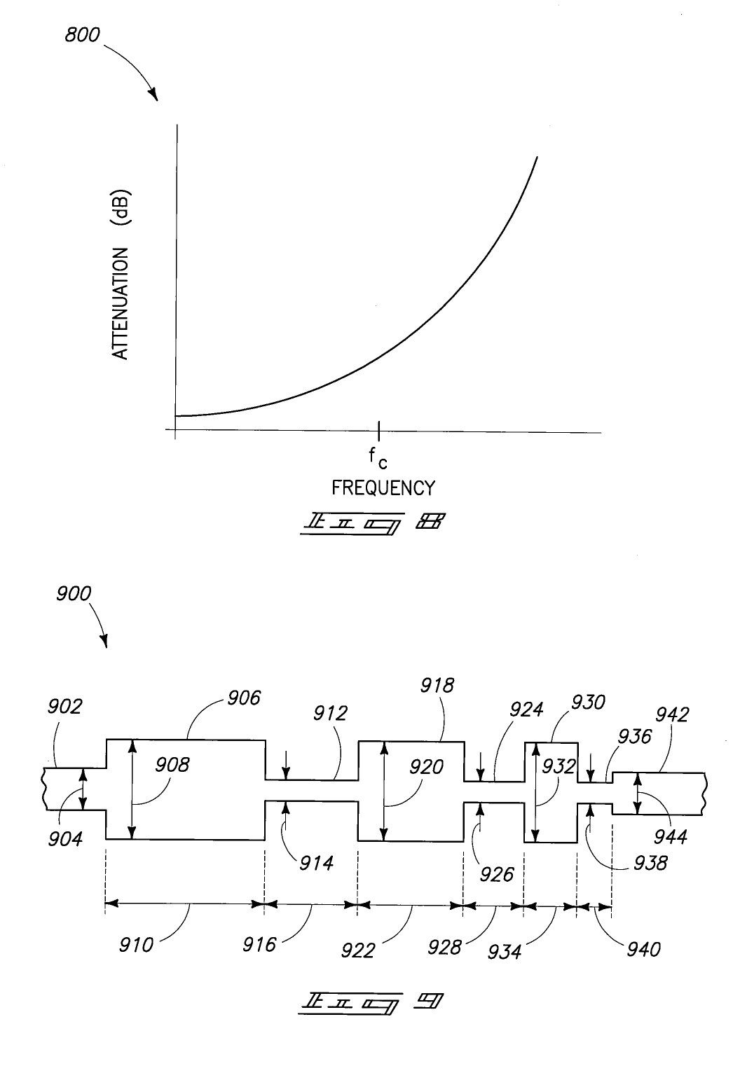

Referring to FIG. 9, a stepped-impedance transmission-line filter 900 is illustrated. Filter 900 includes segments 902, 906, 912, 918, 924, 930, 936, and 942. These segments are physically and electrically connected together and may be formed in a patterned layer of conductive material on a substrate. The complex impedance of the segments may depend on the dimensions of the segments.

Segments 902 and 942 have a first complex impedance. Segment 902 has a width 904, which is substantially the same as a width 944 of segment 942. Widths 904 and 944 may be chosen to have a desired complex impedance.

Segments 906, 918, and 930 have widths 908, 920, and 932 respectively. These widths may be substantially the same and may be larger than width 904. Due to their larger width, segments 906, 918, and 930 may have more capacitance than segments 902 and 942. As a result, segments 906, 918, and 930 may act as capacitors relative to segments 902 and 942.

An amount of capacitance provided by segments 906, 918, and 930 may depend on lengths 910, 922, and 934 of segments 906, 918, and 930. For example, segment 906 may provide more capacitance than either segment 918 or segment 930 if segment 906 is longer than segments 918 and 930.

Segments 912, 924, and 936 have widths 914, 926, and 938 respectively. These widths may be substantially the same and may be smaller than width 904. As a result of their smaller widths, segments 912, 924, and 936 may have a complex impedance that is greater than the first complex impedance. Due to this increased complex impedance, segments 912, 924, and 936 may act as inductors relative to segments 902 and 942.

An amount of inductance provided by segments 912, 924, and 936 may depend on lengths 916, 928, and 940 of segments 912, 924, and 936. For example, segment 912 may provide more inductance than either segment 924 or segment 936 if segment 912 is longer than segments 924 and 936.

Filter 900 may be characterized as having three stages, the first stage including segments 906 and 912, the second stage including segments 918 and 924, and the third stage including segments 930 and 936. Using known filter design techniques, the lengths and widths of segments 906, 912, 918, 924, 930, and 936 may be selected to provide a desired frequency response.

For example, the lengths and widths may be chosen so that filter 900 has a selected cutoff frequency and provides a selected amount of attenuation at a selected frequency, the selected frequency being higher than the cutoff frequency. The cutoff frequency may be related to an amount of capacitive reactance provided by segments 906, 918, and 930 of filter 900 and an amount of inductive reactance provided by segments 912, 924, and 936 of filter 900.

The known filter design techniques may yield a number of stages the filter should have as well as the lengths and widths for the segments of each stage.

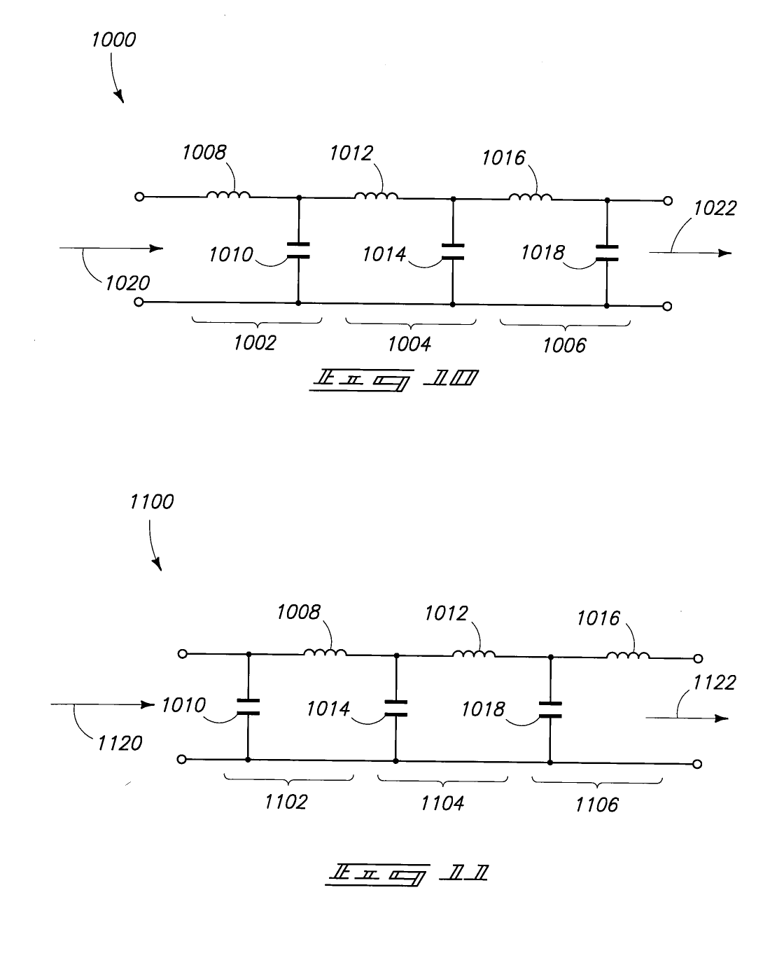

Referring to FIG. 10, a schematic representation of a low-pass filter 1000 is illustrated. Filter 1000 includes three stages 1002, 1004, and 1006. Stage 1002 includes an inductor 1008 and a capacitor 1010, stage 1004 includes an inductor 1012 and a capacitor 1014, and stage 1006 includes an inductor 1016 and a capacitor 1018. Inductor 1008 is connected to an input 1020 of filter 1000 and capacitor 1018 is connected to an output 1022 of filter 1000.

Signals presented at input 1020 of filter 1000 having a frequency higher than a cutoff frequency of filter 1000 may be significantly attenuated at output 1022 (e.g. by 25 db), while signals presented at input 1020 having a frequency lower than the cutoff frequency may be minimally attenuated(e.g. by less than 3 db) at output 1022.

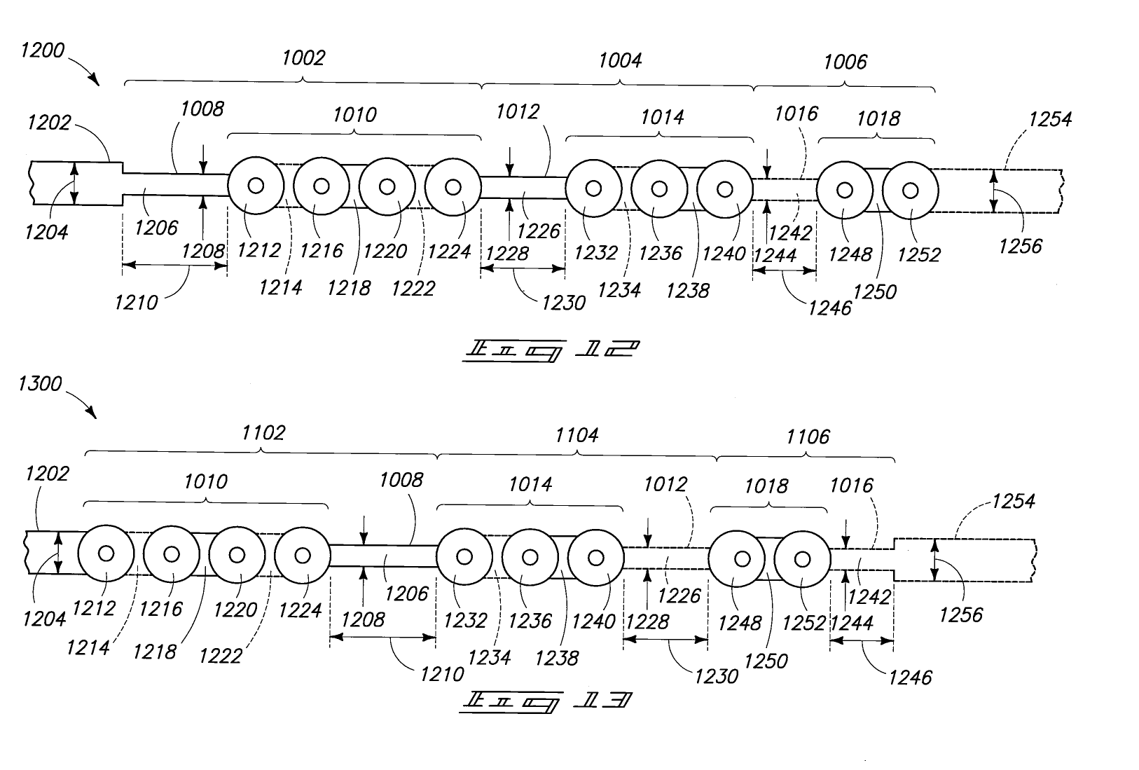

Referring to FIG. 11, a schematic representation of another low-pass filter 1100 is illustrated. Filter 1100 includes the capacitors and inductors of filter 1000 in an alternative arrangement. Filter 1100 includes three stages 1102, 1104, and 1106. Stage 1102 includes inductor 1008 and capacitor 1010, stage 1104 includes inductor 1012 and capacitor 1014, and stage 1106 includes inductor 1016 and capacitor 1018. Capacitor 1010 is connected to an input 1120 and inductor 1016 is connected to an output 1122.

Signals presented at input 1120 having a frequency higher than a cutoff frequency of filter 1100 may be significantly attenuated at output 1122 (e.g., by 25 db), while signals presented at input 1120 having a frequency lower than the cutoff frequency may be minimally attenuated (e.g. by less than 3 db) at output 1122.

Filters 1000 and 1100 may be implemented as stepped-impedance transmission-line filters. In fact, filter 1100 may serve as a schematic representation of filter 900 described above.

Alternatively, filters 1000 and 1100 may be implemented as modified stepped-impedance transmission-line filters in which via-pad-stack capacitors, such as via-pad-stack capacitor 101 described above, are substituted for capacitive segments 906, 918, and 930 of FIG. 9. Substituting via-pad-stack capacitors for segments 906, 918, and 930 may be advantageous because doing so may consume less board area than implementing the filter as a stepped-impedance transmission-line filter.

When implemented on a multi-layer printed circuit board, filters 1000 and 1100 may advantageously filter unwanted high-frequency signals present on a circuit trace connecting two or more electronic components mounted on the printed circuit board. For example, the filters may attenuate undesirable high-frequency noise transmitted on a signal trace by a multi-gigahertz phase locked loop of a SerDes. If left unfiltered, the noise may be radiated by the printed circuit board or packaging to which the printed circuit board is mounted. Filtering such noise may be helpful in ensuring that a printed circuit board is compliant with electromagnetic emissions standards.

Referring to FIG. 12, a modified stepped-impedance transmission-line filter 1200 is illustrated. Filter 1200 is an example embodiment of filter 1000 of FIG. 10. Filter 1200 is a three-stage filter that includes input node 1202, output node 1254, and stages 1002, 1004, and 1006. Stage 1002 includes inductor 1008 and capacitor 1010, stage 1004 includes inductor 1012 and capacitor 1014, and stage 1006 includes inductor 1016 and capacitor 1018.

Filter 1200 includes many segments of transmission line (1202, 1206, 1214, 1218, 1222, 1226, 1234, 1238, 1242, 1250, and 1254) having various widths. The transmission-line segments may be implemented in at least two different ways. When implemented as microstrip segments on a substrate (like segments 612 and 614 on substrate 154 illustrated in FIG. 6), the transmission-line segments may be portions of a patterned layer of conductive material (e.g., the patterned layer of ply 102 or the bottom patterned layer of ply 142) on a substrate (e.g., substrate 154 or substrate 155). Alternatively, the transmission-line segments may be stripline segments.

Segments 1202, 1206, 1218, 1226, 1238, and 1250 are illustrated with solid lines to indicate that these segments are part of a first ply of a multi-layer printed circuit board (e.g., ply 102). In some configurations, the first ply may be a top ply of the multi-layer printed circuit board. From a plan view of the multi-layer printed circuit board, the segments that are part of the first ply may be visible. Other plies of the multi-layer printed circuit board, however, might not be visible.

Accordingly, segments 1214, 1222, 1234, 1242, and 1254 are illustrated with dashed lines to indicate that these segments are part of a second ply of a multi-layer printed circuit board. In some configurations, the second ply may be a bottom ply (e.g., ply 142) of the multi-layer printed circuit board.

In some embodiments, the first ply might not be the top layer of the multi-layer printed circuit board and the second ply might not be the bottom layer of the mutli-layer printed circuit board. Furthermore, some of the segments may be part of plies other than the first and second plies.

In one embodiment, width 1204 of input node 1202 may be selected so input node 1202 has a first complex impedance. The first complex impedance may match a complex impedance of pins of electronic components mounted on the printed circuit board. For example, the complex impedance may be 50 Ohms. Width 1256 of output node 1254 may be substantially the same as width 1204 so that input node 1202 and output node 1254 have substantially the same complex impedance.

Inductor 1008 includes segment 1206 having a width 1208 and a length 1210. Width 1208 may be smaller than width 1204. As a result, segment 1206 may have a complex impedance greater than the first complex impedance of input node 1202 and output node 1254. Consequently, segment 1206 may provide inductive reactance to stage 1002.

Similarly, segments 1226 and 1242 may have widths 1228 and 1244 respectively, which are smaller than width 1204. Consequently, segment 1226 may provide inductive reactance to stage 1004 and segment 1244 may provide inductive reactance to stage 1006 since these segments may have a complex impedance greater than the first complex impedance.

In one embodiment, widths 1208, 1228, and 1244 may be substantially the same and segments 1206, 1226, and 1242 may have substantially the same complex impedance. In some configurations, lengths 1210, 1230, and 1246 may be different relative to one another. Due to the differences in lengths, the amounts of inductive reactance provided by inductors 1008, 1012, and 1016 may be different relative to one another. For example, if length 1210 is larger than length 1230, segment 1206 may provide more inductive reactance than segment 1226.

As illustrated in FIG. 12, in one embodiment capacitor 1010 may include four via-pad-stack capacitors 1212, 1216, 1220, and 1224, capacitor 1014 may include three via-pad-stack capacitors 1232, 1236, and 1240, and capacitor 1018 may include two via-pad-stack capacitors 1248 and 1252.

The via-pad-stack capacitors of FIG. 12 may each be individual implementations of via-pad-stack capacitor 101 described in detail above in relation to FIGS. 1-7. As a result, each of the via-pad-stack capacitors of FIG. 12 may include a plurality of conductive pads in electrical contact with a via that extend radially outward from the via and overlap a plurality of ground-plane layers.

As illustrated in FIG. 12, the outer circles of the via-pad-stack capacitors may be pads (e.g., pads substantially similar to pad 158 of FIGS. 1-7). Of course, the via-pad-stack capacitors of FIG. 12 may include other pads not illustrated in FIG. 12 (e.g., pads substantially similar to pad 168). The visible inner circles of the via-pad-stack capacitors of FIG. 12 may be vias (e.g., vias substantially similar to via 144 of FIGS. 1-7).

In some embodiments, the via-pad-stack capacitors of FIG. 12 may have substantially identical dimensions. In other embodiments, the via-pad-stack capacitors of FIG. 12 may have different dimensions relative to one another. For example, via-pad-stack capacitor 1212 may include more pads than via-pad-stack capacitor 1216 and/or via-pad-stack capacitor 1212 may have pads with larger surface area (e.g., larger diameters) than the pads of via-pad-stack capacitor 1216.

The via-pad-stack capacitors of FIG. 12 may each include a top pad, located on a top surface of a multi-layer printed circuit board and located at a first end of a via of the via-pad-stack capacitor, and a bottom pad, located on a bottom surface of the multi-layer printed circuit board and located at a second end of the via.

In one embodiment, input node 1202 and segment 1206 may be on the top surface and may be connected to each other. Segment 1206 may also be connected to a top pad of via-pad-stack capacitor 1212.

As illustrated in FIG. 12, segments 1218, 1226, 1238, and 1250 may be located on the top surface and may respectively connect top pads of via-pad-stack capacitors 1216 and 1220, 1224 and 1232, 1236 and 1240, and 1248 and 1252 together. Segments 1214, 1222, 1234, and 1242 may be located on the bottom surface and may respectively connect bottom pads of via-pad-stack capacitors 1212 and 1216, 1220 and 1224, 1232 and 1236, and 1240 and 1248 together. A bottom pad of via-pad-stack capacitor 1252 may be connected to output node 1254, which may be located on the bottom surface.

As was described above in relation to FIGS. 1-7, a via-pad-stack capacitor may include a first electrode including the via and the pads and a second electrode including ground-plane layers. Since pads of via-pad-stack capacitors 1212, 1216, 1220, and 1224 are connected together by segments 1214, 1218, and 1222, the vias and pads of these via-pad-stack capacitors may be electrically connected and may form a first electrode of capacitor 1010. The vias of via-pad-stack capacitors 1212, 1216, 1220, and 1224 may be described as being serially connected.

Furthermore, ground-plane layers of the multi-layer printed circuit board of FIG. 12 may be common to via-pad-stack capacitors 1212, 1216, 1220, and 1224 and may form a second electrode of capacitor 1010. Since the first electrode and second electrode are common to via-pad-stack capacitors 1212, 1216, 1220, and 1224, these via-pad-stack capacitors may be described as being connected in parallel. Accordingly, the capacitances of via-pad-stack capacitors 1212, 1216, 1220, and 1224 may be added together and the sum of these capacitances may be the capacitance of capacitor 1010.

The capacitance of capacitor 1014 may be similarly determined from the capacitances of via-pad-stack capacitors 1232, 1236, and 1240 and the capacitance of capacitor 1018 may be similarly determined from the capacitances of via-pad-stack capacitors 1248 and 1252. Capacitors 1010, 1014, and 1018 may contribute capacitive reactance to filter 1200.

The widths of segments 1214, 1218, 1222, 1234, 1238, and 1250 may be substantially the same as width 1204 so that these segments have substantially the same complex impedance as input node 1202.

Filter 1200 may have advantages over filter 900. For example, the amount of printed circuit board area consumed by capacitors 906, 918, and 930 of filter 900 may be significantly larger than the amount of printed circuit board area consumed by capacitors 1010, 1014, and 1018 of filter 1200. This might not be apparent based on the lengths of capacitors 906, 918, and 930 in FIG. 9. The scale used in FIG. 9, however, is not necessarily the same as the scale used in FIG. 12.

This reduction in consumed area may make it easier to route signal traces between electronic components mounted on the printed circuit board, and, in some embodiments, may reduce the number of plies used in a multi-layer printed circuit board when compared with filter 900.

For some printed circuit boards, implementing filter 900 may be impractical because it may be too difficult to set aside enough uninterrupted space on a single ply of the printed circuit board for filter 900. In contrast, filter 1200 uses less board space and may have inductor segments on two different plies of the printed circuit board. This is advantageous because filter 1200 does not require uninterrupted space on a single ply of the printed circuit board like filter 900, which is beneficial for densely-packed multi-layer printed circuit boards.

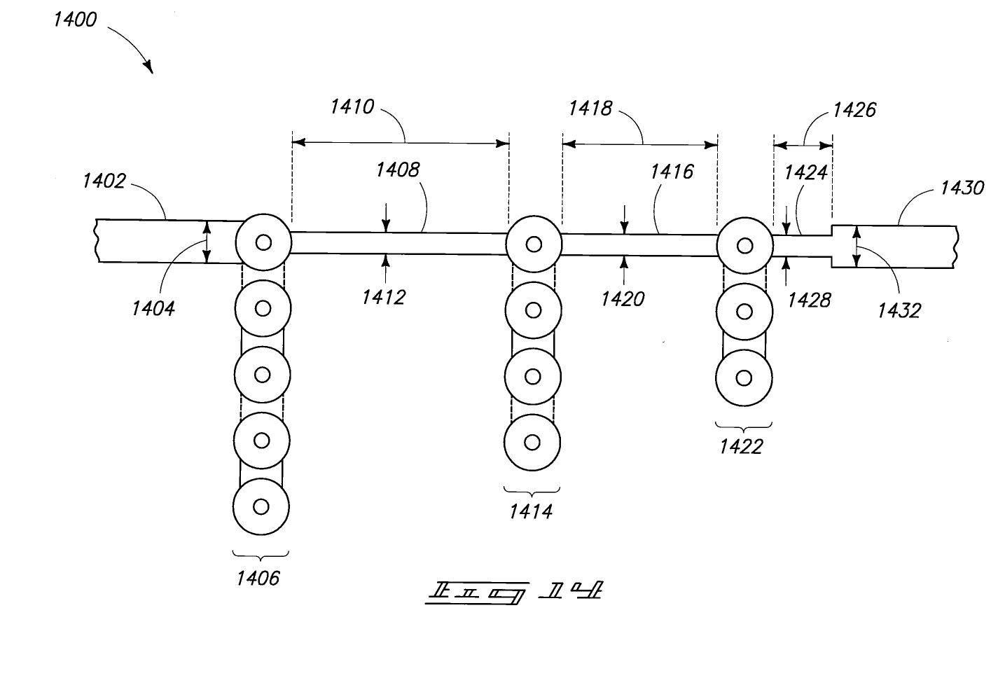

Referring to FIG. 13, a modified stepped-impedance transmission-line filter 1300 is illustrated. Filter 1300 is an example embodiment of filter 1100 of FIG. 11. Filter 1300 includes three stages 1102, 1104, and 1106. Filter 1300 is similar to filter 1200 in that it includes input node 1202, output node 1254, capacitors 1010, 1014, and 1018 and inductors 1008, 1012, and 1016. However, the arrangement of the capacitors and inductors in filter 1300 is different than in filter 1200. As a result, filter 1300 implements the schematic of FIG. 11 rather than the schematic of FIG. 10.

In FIG. 13, segments 1202, 1218, 1206, 1238, and 1250 are illustrated with solid lines to indicate that these segments are part of a first ply of a multi-layer printed circuit board (e.g., ply 102). In some configurations, the first ply may be a top ply of the multi-layer printed circuit board. From a plan view of the multi-layer printed circuit board, the segments that are part of the first ply may be visible. Other plies of the multi-layer printed circuit board, however, might not be visible.

Accordingly, segments 1214, 1222, 1234, 1226, and 1242 are illustrated with dashed lines to indicate that these segments are part of a second ply of a multi-layer printed circuit board. In some configurations, the second ply may be a bottom ply (e.g., ply 142) of the multi-layer printed circuit board.

In some embodiments, the first ply might not be the top layer of the multi-layer printed circuit board and the second ply might not be the bottom layer of the mutli-layer printed circuit board. Furthermore, some of the segments may be part of plies other than the first and second plies.

In one embodiment, input node 1202 may be on a top surface of the multi-layer printed circuit board and may be connected to a top pad of via-pad-stack capacitor 1212.

As illustrated in FIG. 13, segments 1218, 1206, 1238, and 1250 may be located on the top surface and may respectively connect top pads of via-pad-stack capacitors 1216 and 1220, 1224 and 1232, 1236 and 1240, and 1248 and 1252 together. Segments 1214, 1222, 1234, and 1226 may be located on the bottom surface and may respectively connect bottom pads of via-pad-stack capacitors 1212 and 1216, 1220 and 1224, 1232 and 1236, and 1240 and 1248 together. A bottom pad of via-pad-stack capacitor 1252 may be connected to output node 1254 by segment 1242, which may be located on the bottom surface.

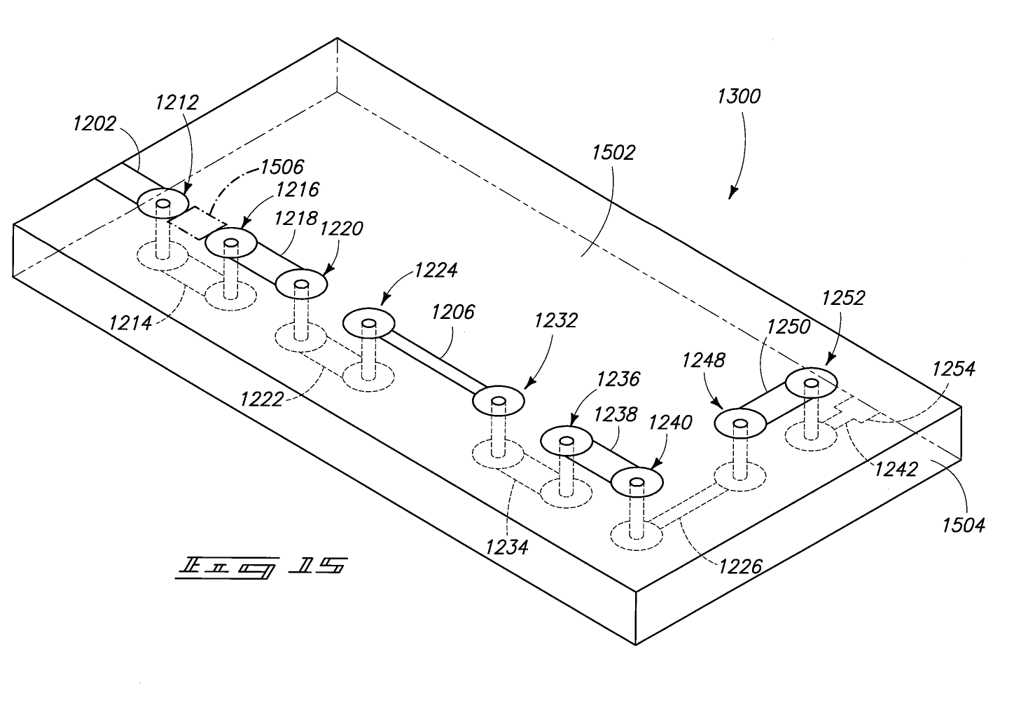

Referring to FIG. 14, a modified stepped-impedance transmission-line filter 1400 is illustrated. Like filters 1200 and 1300, filter 1400 is a low-pass filter having a cutoff frequency. Filter 1400 includes input node 1402 having width 1404; output node 1430 having width 1432; capacitors 1406, 1414, and 1422; and inductors 1408, 1416, and 1424.

Inductors 1408, 1416, and 1424 have lengths 1410, 1418, and 1426 and widths 1412, 1420, and 1428 respectively. In one embodiment, widths 1412, 1420, and 1428 are substantially the same and are smaller than widths 1404 and 1432 so that inductors 1408, 1416, and 1424 have a greater complex impedance than input node 1402 and output node 1430.

Capacitors 1406, 1414, and 1422 include different numbers of via-pad-stack capacitors like via-pad-stack capacitor 101 described above and are connected by segments of transmission line. Consequently, capacitors 1406, 1414, and 1422 contribute different amounts of capacitive reactance to filter 1400 relative to one another.

The via-pad-stack capacitors of capacitor 1406 are serially connected in a stub fashion so that one via-pad-stack capacitor is physically connected to inductor 1408 and the other via-pad-stack capacitors of capacitor 1406 are connected together in a chain with the last via-pad-stack capacitor of the chain being unconnected to an electrically conductive node apart from the other via-pad-stack capacitors of capacitor 1406. Capacitors 1414 and 1422 are similarly connected in stub fashion.

The number of via-pad-stack capacitors in the stubs; lengths 1410, 1418, and 1426; and widths 1412, 1420, and 1428 may be selected so that filter 1400 provides a desired amount of attenuation and a desired cutoff frequency.

According to another aspect of the invention, a printed circuit board includes a first via extending through a printed circuit board and has a first pad on a top surface of the printed circuit board and a second pad on a bottom surface of the printed circuit board. The first via is configured to inhibit current entering the first via at the first pad from leaving the first via except through the second pad.

The printed circuit board also includes a second via extending through the printed circuit board and having a third pad on the top surface and a fourth pad on the bottom surface. The second via is configured to inhibit current entering the second via at the fourth pad from leaving the second via except through the third pad, the second via being adjacent to the first via.

The printed circuit board may further include a plurality of conductive pads extending radially outward from the vias, individual conductive pads of the plurality being in electrical contact with one or more of the first via and the second via, and a plurality of ground-plane layers comprising electrically conductive material elevationally directly above the plurality of conductive pads. The ground layers of the plurality may be electrically connected to each other and electrically isolated from the plurality of conductive pads. The first via, second via, and the plurality of conductive pads may form a first electrode of a capacitor and the plurality of ground-plane layers may form a second electrode of the capacitor.

The printed circuit board also includes a node electrically connecting the second pad and the fourth pad. The node is configured to inhibit current entering the node from the first via from leaving the node except through the second via. The node may include a segment of transmission line.

An area of the top surface located between the first pad and the third pad and physically contacting the first pad and the third pad may be free from transmission-line segments.

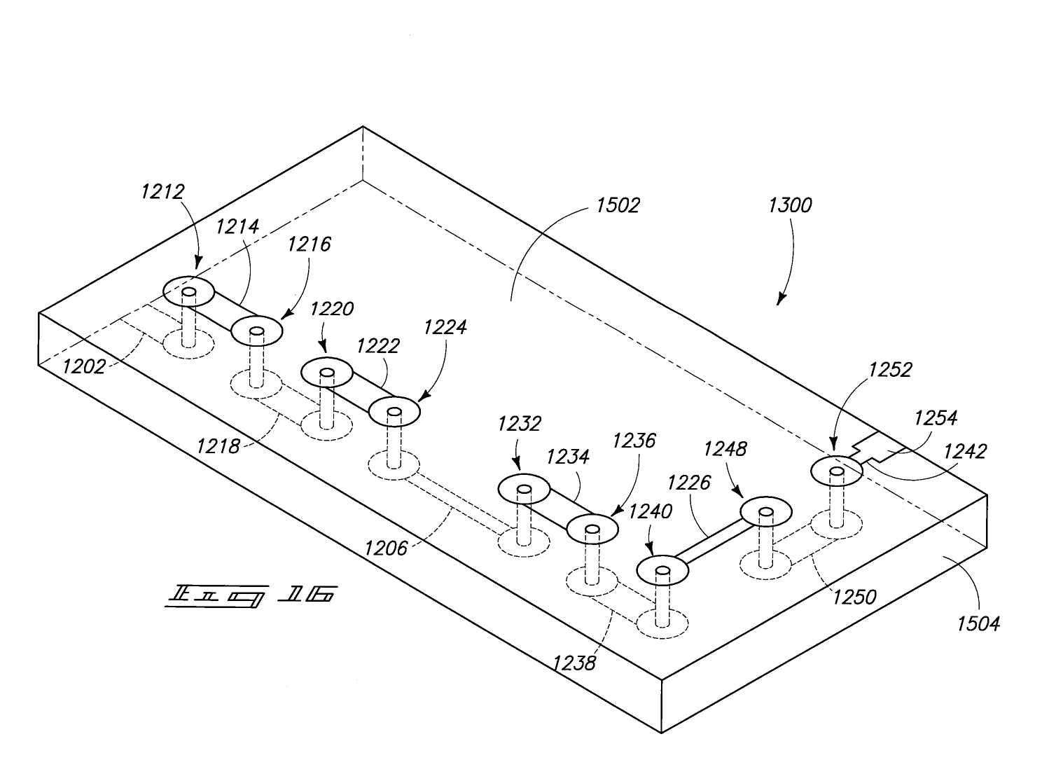

Referring to FIG. 15, an isometric view of one configuration of filter 1300 (described above in relation to FIG. 13) is illustrated. Input node 1202 along with segments 1218, 1206, 1238, and 1250 and top pads of via-pad-stack capacitors 1212, 1216, 1220, 1224, 1232, 1236, 1240, 1248, and 1252 are located on top surface 1502 of a multi-layer printed circuit board.

Output node 1254 along with segments 1214, 1222, 1234, 1226, and 1242 and bottom pads of via-pad-stack capacitors 1212, 1216, 1220, 1224, 1232, 1236, 1240, 1248, and 1252 are located on bottom surface 1504 of the multi-layer printed circuit board and are illustrated in phantom. Other pads of via-pad-stack capacitors 1212, 1216, 1220, 1224, 1232, 1236, 1240, 1248, and 1252 are not illustrated for simplicity.

As was described above, a via-pad-stack capacitor may have two electrodes, a first electrode including the via and the pads and a second electrode including the ground-plane layers. Since the first electrode might not be in electrical contact with the second electrode, substantially all of the current that enters one end of a via-pad-stack capacitor may leave the other end of the via-pad-stack capacitor.

For example, substantially all of a current entering the top pad of via-pad-stack capacitor 1212 from input node 1202 may leave the bottom pad of via-pad-stack capacitor 1212 and flow into segment 1214 because the first electrode of via-pad-stack capacitor 1212 might not be electrically connected to a node other than input node 1202 and segment 1214. Of course, some small amount of leakage current may flow from the first electrode of via-pad-stack capacitor 1212 to the second electrode of via-pad-stack capacitor 1212 and there may be a delay between when the current flows into via-pad-stack capacitor 1212 and when it flows out of via-pad-stack capacitor 1212 due to charging and discharging. Generally, however, current that flows into via-pad-stack capacitor 1212 eventually flows out of via-pad-stack capacitor 1212 since the via and the pads of via-pad-stack capacitor 1212 are not electrically connected to an electrically conductive node other than input node 1202 and segment 1214.

Thus, via-pad-stack capacitor 1212 can be said to inhibit current flowing into its top pad from leaving via-pad-stack capacitor 1212 except through its bottom pad. Similarly, via-pad-stack capacitor 1212 can be said to inhibit current flowing into its bottom pad from leaving via-pad-stack capacitor 1212 except through its top pad.

Segment 1214 may be referred to as an electrically conductive node joining the bottom pads of via-pad-stack capacitors 1212 and 1216. Segment 1214 might not be physically connected to another electrically conductive node other than the bottom pads of via-pad-stack capacitors 1212 and 1216. Consequently, substantially all of a current entering segment 1214 from the bottom pad of via-pad-stack capacitor 1212 may leave segment 1214 and enter the bottom pad of via-pad-stack capacitor 1216. Likewise, substantially all of a current entering segment 1214 from the bottom pad of via-pad-stack capacitor 1216 may leave segment 1214 and enter the bottom pad of via-pad-stack capacitor 1212.

As illustrated in FIG. 15, via-pad-stack capacitors 1212 and 1216 may be adjacent to one another and may be as close to one another as design rules associated with the multi-layer printed circuit board allow. In some embodiments, area 1506 between via-pad-stack capacitors 1212 and 1216 that physically contacts both via-pad-stack capacitors 1212 and 1216 may be free from any transmission-line segments. In other words, there might not be any transmission-line segments (e.g., microstrip lines) that run between via-pad-stack capacitors 1212 and 1216 on surface 1502.

Referring to FIG. 16, an isometric view of another configuration of filter 1300 (described above in relation to FIG. 13) is illustrated. In this configuration, input node 1202 along with segments 1218, 1206, 1238, and 1250 and bottom pads of via-pad-stack capacitors 1212, 1216, 1220, 1224, 1232, 1236, 1240, 1248, and 1252 are located on bottom surface 1504 of a multi-layer printed circuit board and are illustrated in phantom.

Output node 1254 along with segments 1214, 1222, 1234, 1226, and 1242 and top pads of via-pad-stack capacitors 1212, 1216, 1220, 1224, 1232, 1236, 1240, 1248, and 1252 are located on top surface 1502 of the multi-layer printed circuit board. Other pads of via-pad-stack capacitors 1212, 1216, 1220, 1224, 1232, 1236, 1240, 1248, and 1252 are not illustrated for simplicity.

The filters described herein may be designed, at least in part, with the aid of computer programming (e.g., software, firmware, etc.).

According to another aspect of the invention, an article of manufacture includes media having programming configured to receive a cutoff frequency and determine a length of an inductive portion of one stage of a low-pass stepped-impedance transmission-line filter based on the cutoff frequency. In some embodiments, the programming may also be configured to determine a width of the inductive portion of the one stage of the low-pass stepped-impedance transmission-line filter.

The programming is also configured to determine an amount of capacitance to be included in the one stage of the filter based on the cutoff frequency, to determine a quantity of printed circuit board vias that if connected will provide the amount of capacitance, and to provide the quantity, for example, to a user of the programming.

The programming may be configured to determine a quantity of vias and inductive portion width and length for other stages of the filter as well. The programming may be further configured to receive a desired amount of attenuation and determine a number of stages of the filter based on the cutoff frequency and the desired amount of attenuation.

The article of manufacture includes media including programming configured to cause processing circuitry (e.g., a microprocessor) to perform processing that executes one or more of the methods described above. The programming may be embodied in a computer program product(s) or article(s) of manufacture, which can contain, store, or maintain programming, data, and/or digital information for use by or in connection with an instruction execution system including processing circuitry. In some cases, the programming may be referred to as software, hardware, or firmware.

For example, the media may be electronic, magnetic, optical, electromagnetic, infrared, or semiconductor media. Some more specific examples of articles of manufacture including media with programming include, but are not limited to, a portable magnetic computer diskette (such as a floppy diskette or a ZIP® disk manufactured by the lomega Corporation of San Diego, Calif.), hard drive, random access memory, read only memory, flash memory, cache memory, and/or other configurations capable of storing programming, data, or other digital information.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

The invention claimed is:

1. An electronic filter comprising:
a filter stage comprising:
a first segment of transmission line formed on a printed circuit board, the first segment having a first complex impedance and being configured to provide at least part of an inductive reactance of the filter stage; and
one or more vias extending through the printed circuit board, a first end of a first one of the one or more vias being electrically connected to a first end of the first segment of transmission line, the one or more vias being configured to provide at least part of a capacitive reactance of the filter stage; and
an input node comprising a second segment of transmission line formed on the printed circuit board, the second segment having a second complex impedance, the second complex impedance being larger than the first complex impedance and the second segment being connected to either a second end of the first segment of transmission line, to the first end of the first one of the one or more vias, or to an end of a second one of the one or more vias.

2. The electronic filter of claim 1 wherein the first segment and the second segment are on a same side of the printed circuit board relative to one another.

3. The electronic filter of claim 1 wherein the first segment and the second segment are on different sides of the printed circuit board relative to one another.

4. The electronic filter of claim 1 wherein the first segment and the second segment have different widths relative to one another.

5. The electronic filter of claim 1 wherein the one or more vias are serially connected.

6. The electronic filter of claim 1 wherein the printed circuit board is a multi-layer printed circuit board and the filter stage further comprises:
a plurality of conductive pads in electrical contact with the one or more vias and extending radially outward from the one or more vias; and
a plurality of ground-plane plies comprising patterned layers of electrically conductive material, each ground-plane ply of the plurality being elevationally directly above at least one conductive pad of the plurality of conductive pads, the plurality of ground-plane plies being electrically connected to each other and electrically isolated from the plurality of conductive pads, the one or more vias and the plurality of conductive pads forming a first electrode of a capacitor and the electrically connected plurality of ground-plane layers forming a second electrode of the capacitor.

7. The electronic filter of claim 1 wherein the one or more vias comprise two or more vias serially connected together with one end of the serially connected two or more vias being connected to the first segment of transmission line and the other end of the serially connected two or more vias not being electrically connected to any other conductive node of the printed circuit board.

8. The electronic filter of claim 1 wherein the filter stage is a first filter stage, the one or more vias comprise a first set of one or more vias, and the electronic filter further comprises:
a second filter stage comprising a third segment of transmission line formed on the printed circuit board and having the first complex impedance and a length different than a length of the first segment of transmission line; and
a second set of two or more serially connected vias extending through the printed circuit board, the second set comprising a different quantity of vias than the first set.

9. The electronic filter of claim 8 further comprising an output node comprising a fourth segment of transmission line formed on the printed circuit board, the fourth segment having the second complex impedance and being physically connected to the third segment of transmission line.

10. The electronic filter of claim 1 wherein the filter stage is a lowpass filter stage configured to substantially attenuate signals presented at the input node having a frequency higher than a cutoff frequency of the filter stage and minimally attenuate signals presented at the input node having a frequency lower than the cutoff frequency.

11. The electronic filter of claim 1 wherein the first segment of transmission line comprises a first segment of stripline or microstrip and the second segment of transmission line comprises a second segment of stripline or microstrip.

12. A multi-layer printed circuit board comprising:
a first volume;
a second volume contained by the first volume;
a third volume comprising a section of the first volume that is not within the second volume;
a plurality of plies including:
a ply comprising a conductive pad on a first substrate, the conductive pad extending within the first volume, the second volume, and the third volume, but not outside of the first volume;
at least one ground ply comprising a patterned layer of conductive material on a second substrate, a portion of the patterned layer extending within the third volume but not extending within the second volume, the portion being elevationally directly above the conductive pad; and
a via electrically connected to the conductive pad and extending through the plurality of plies and through the second volume.

13. The multi-layer printed circuit board of claim 12 wherein the conductive pad is circular and fills a first cross section of the third volume and the portion of the conductive material fills a second cross section of the third volume.

14. The multi-layer printed circuit board of claim 12 wherein the third volume surrounds the via and the via does not extend into the third volume.

15. The multi-layer printed circuit board of claim 12 wherein the first substrate electrically insulates the portion of the patterned layer from the conductive pad and the second substrate electrically insulates the via from the portion of the patterned layer.

16. The multi-layer printed circuit board of claim 12 wherein the first substrate is in physical contact with both the conductive pad and the patterned layer of conductive material.

17. The multi-layer printed circuit board of claim 12 wherein the portion of the conductive material is a first portion and further comprising:
a fourth volume;
at least one additional ply comprising a second patterned layer of conductive material on a third substrate, a second portion of the second patterned layer of conductive material extending outside of the fourth volume but not extending within the first volume or the second volume; and
wherein the first volume is within the fourth volume and the first portion extends outside of the fourth volume.

18. A printed circuit board capacitor comprising:
a first electrode comprising:
a via extending at least partially through a multi-layer printed circuit board; and
a plurality of conductive pads in electrical contact with the via and extending radially outward from the via; and
a second electrode electrically isolated from the first electrode and comprising a plurality of ground-plane layers of the printed circuit board, the plurality of ground-plane layers comprising electrically conductive material overlapping the plurality of conductive pads.

19. The printed circuit board capacitor of claim 18 wherein individual conductive pads of the plurality of conductive pads are comprised by different plies of the multi-layer printed circuit board relative to one another.

20. The printed circuit board capacitor of claim 18 wherein the via comprises a cylindrically shaped electrically conductive material positioned within an opening formed in the printed circuit board.

21. The printed circuit board capacitor of claim 18 wherein at least fifty percent of the surface area of at least one of the conductive pads of the plurality is elevationally directly below the electrically conductive material.

22. The printed circuit board capacitor of claim 18 wherein individual conductive pads of the plurality surround different cross sections of the via relative to one another.

23. The printed circuit board capacitor of claim 18 wherein the ground-plane layers of the plurality are interposed with the plurality of conductive pads.

24. The printed circuit board capacitor of claim 18 wherein the plurality of conductive pads includes at least six pads.

25. The printed circuit board capacitor of claim 18 wherein the ground-plane layers of the plurality are electrically connected to each other.

26. A printed circuit board comprising:
a first via extending through a printed circuit board and having a first pad on a top surface of the printed circuit board and a second pad on a bottom surface of the printed circuit board and configured to inhibit current entering the first via at the first pad from leaving the first via except through the second pad;
a second via extending through the printed circuit board and having a third pad on the top surface and a fourth pad on the bottom surface and configured to inhibit current entering the second via at the fourth pad from leaving the second via except through the third pad, the second via being adjacent to the first via; and
a node electrically connecting the second pad and the fourth pad and configured to inhibit current entering the node from the first via from leaving the node except through the second via.

27. The printed circuit board of claim 26 wherein an area of the top surface located between the first pad and the third pad and physically contacting the first pad and the third pad is free from transmission-line segments.

28. The printed circuit board of claim 26 further comprising:
a plurality of conductive pads extending radially outward from the vias, individual conductive pads of the plurality being in electrical contact with one or more of the first via and the second via; and
a plurality of ground-plane layers comprising electrically conductive material elevationally directly above the plurality of conductive pads, the ground layers of the plurality being electrically connected to each other and electrically isolated from the plurality of conductive pads;
wherein the first via, second via, and the plurality of conductive pads form a first electrode of a capacitor and the plurality of ground-plane layers form a second electrode of the capacitor.

29. The printed circuit board of claim 26 wherein the node comprises a segment of transmission line.

30. A capacitor forming method comprising:
forming a first printed circuit board ply comprising a conductive pad on a first substrate, the conductive pad having a first area;
forming a second printed circuit board ply comprising a layer of conductive material on a second substrate, the layer of conductive material comprising a first opening surrounded by a portion of the conductive material, the first opening having a second area smaller than the first area;
bonding the first printed circuit board ply to the second printed circuit board ply so that the conductive pad is elevationally directly above the first opening and elevationally directly above the portion of the conductive material; and
forming a second opening extending through the conductive pad, the first substrate, the first opening, and the second substrate.

31. The method of claim 30 wherein the conductive material is a first conductive material and further comprising forming a second conductive material within the second opening and in physical contact with the conductive pad but not in physical or electrical contact with the first conductive material.

32. The method of claim 30 wherein the bonding comprises bonding so that the conductive pad covers an entirety of the first opening.

33. An article of manufacture comprising media comprising programming configured to:
receive a cutoff frequency;
determine a length of an inductive portion of one stage of a low-pass stepped-impedance transmission-line filter based on the cutoff frequency;
determine an amount of capacitance to be included in the one stage of the filter based on the cutoff frequency;
determine a quantity of printed circuit board vias that if connected will provide the amount of capacitance; and
provide the quantity.

34. The article of manufacture of claim 33 wherein the programming is further configured to receive a desired amount of attenuation and determine a number of stages of the filter based on the cutoff frequency and the desired amount of attenuation.

35. The article of manufacture of claim 33 wherein the programming is further configured to determine a width of the inductive portion of the one stage of the low-pass stepped-impedance transmission-line filter.
